(19) United States
(12) Patent Application Publication
(10) Pub. No.: US 2014/0191403 A1
(43) Pub. Date: Jul. 10, 2014

(54) MULTI-DIE SEMICONDUCTOR PACKAGE AND METHOD OF MANUFACTURING THEREOF

(71) Applicant: LSI CORPORATION, Milpitas, CA (US)

(72) Inventor: Ivor G. Barber, Milpitas, CA (US)

(73) Assignee: LSI CORPORATION, Milpitas, CA (US)

(21) Appl. No.: 13/735,272

(22) Filed: Jan. 7, 2013

(51) Int. Cl. H01L 23/538; H01L 21/768

(52) U.S. Cl. CPC H01L 23/5386; H01L 21/768
USPC 257/773; 438/107

(57) ABSTRACT

A multi-die semiconductor package and various methods of manufacturing the same. In one embodiment, the semiconductor package includes: (1) a substrate, (2) a first die coupled to the substrate, the first die having a first set of terminals located along a first edge and bearing a first integrated circuit (IC) that substantially occupies an area of the first die, (3) a second die coupled to the substrate, the second die having a second set of terminals and bearing a second IC that substantially occupies an area of the second die, the first and second ICS being mirror-images of one another and (4) interconnects coupling corresponding terminals of the first and second sets together.

### TECHNICAL FIELD

This application is directed, in general, to semiconductor packages and, more specifically, to a multi-die semiconductor package and methods of manufacturing thereof.

### BACKGROUND

A semiconductor package is a casing, typically made of plastic, glass or ceramic, that houses one or more integrated circuit (“IC”) dies and provides interconnections allowing circuitry associated with the IC die(s) to communicate signals with other circuitry outside of the semiconductor package.

Occasionally semiconductor packages are required to contain two instances of the same circuitry interconnected to cooperate with one another in some manner. Such packages may be assembled by bonding two instances of identical IC dies onto a common substrate, which supports the dies and provides the necessary interconnections, and then forming the casing around the substrate and dies. Assuming the two identical IC dies are placed side by side, the interconnections bridging like terminals in the dies extend, for example, from the left-hand side of the left die to the left-hand side of the right die, which typically means that the underlying interconnections extend underneath the left die. This arrangement continues to be proven and useful.

### SUMMARY

One aspect provides a multi-die semiconductor package. In one embodiment, the semiconductor package includes: (1) a substrate, (2) a first die coupled to the substrate, the first die having a first set of terminals located along a first edge and bearing a first IC that substantially occupies an area of the first die, (3) a second die coupled to the substrate, the second die having a second set of terminals and bearing a second IC that substantially occupies an area of the second die, the first and second ICS being mirror-images of one another and (4) interconnects coupling corresponding terminals of the first and second sets together.

Another aspect provides a method of manufacturing a semiconductor package. In one embodiment, the method includes: (1) coupling a first die to a substrate, the first die having a first set of terminals located along a first edge and bearing a first IC that substantially occupies an area of the first die and (2) coupling a second die to the substrate, the second die having a second set of terminals and bearing a second IC that substantially occupies an area of the second die, the first and second ICs being mirror-images of one another, interconnects coupling corresponding terminals of the first and second sets together.

In another embodiment, the method includes: (1) creating an IC design, (2) creating a first layout of the design that has multiple layers, (3) creating a second layout of the design that is a mirror image of the first layout, corresponding ones of the multiple layers of the first and second layouts being mirror images of one another, (4) employing the first layout to fabricate a first die, (5) employing the second layout to fabricate a second die and (6) collocating the first and second dies in the semiconductor package.

### BRIEF DESCRIPTION

Reference is now made to the following descriptions taken in conjunction with the accompanying drawings, in which:

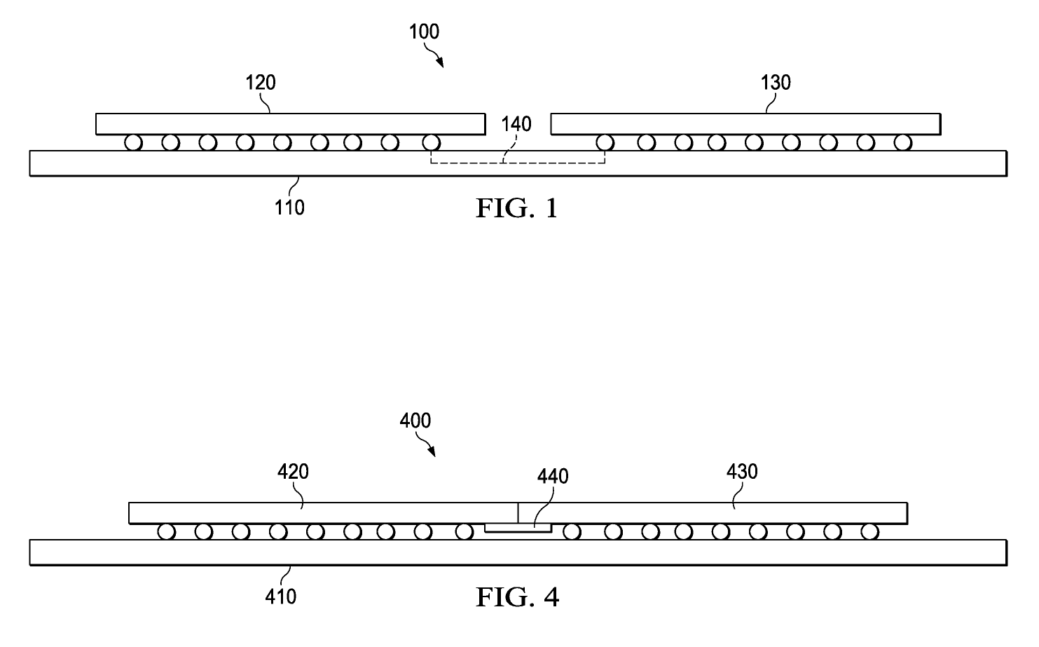

FIG. 1 is an elevational view of one embodiment of a semiconductor package at an intermediate stage of manufacture;

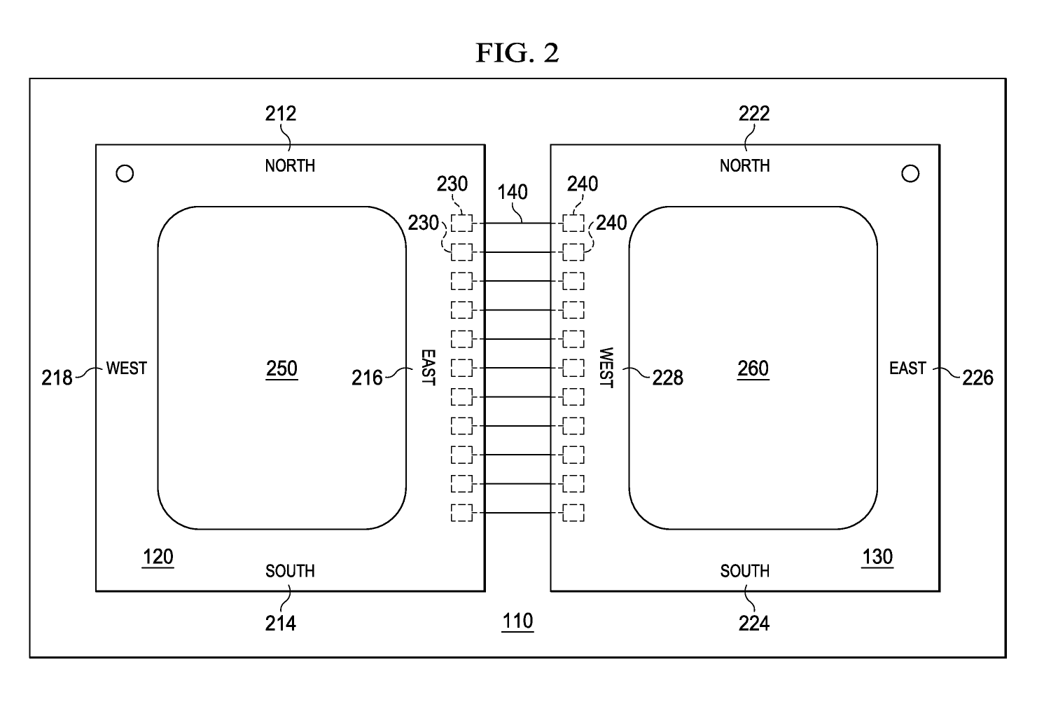

FIG. 2 is a plan view of the semiconductor package of FIG. 1;

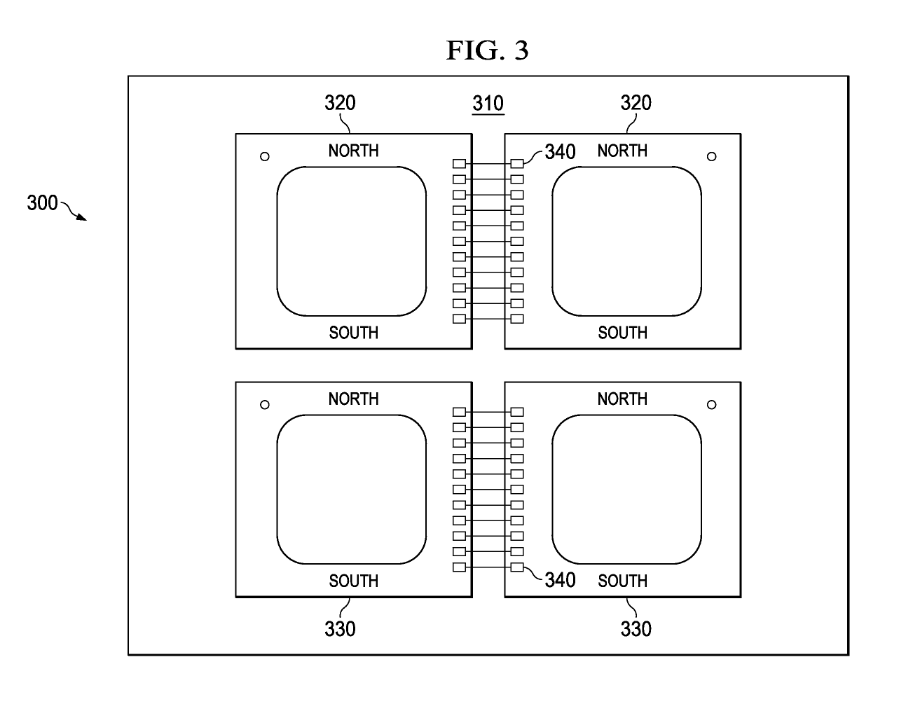

FIG. 3 is a plan view of another embodiment of a semiconductor package at an intermediate stage of manufacture;

FIG. 4 is an elevational view of yet another embodiment of a semiconductor package at an intermediate stage of manufacture;

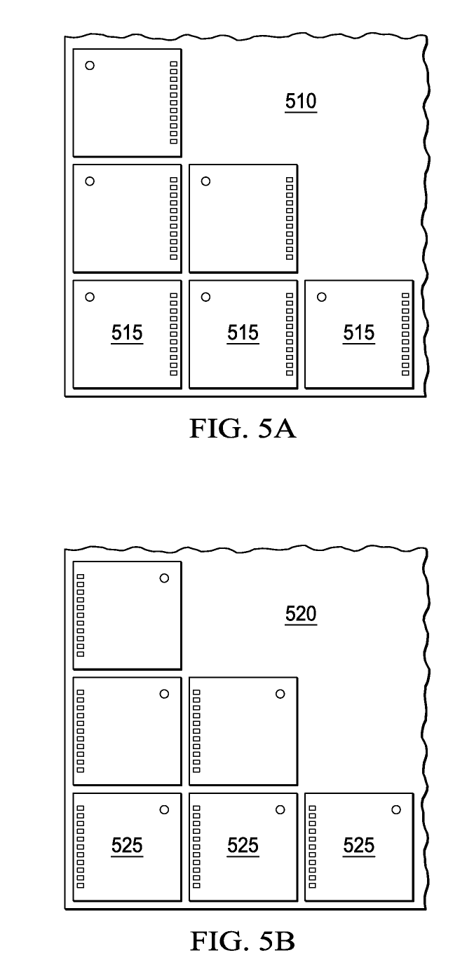

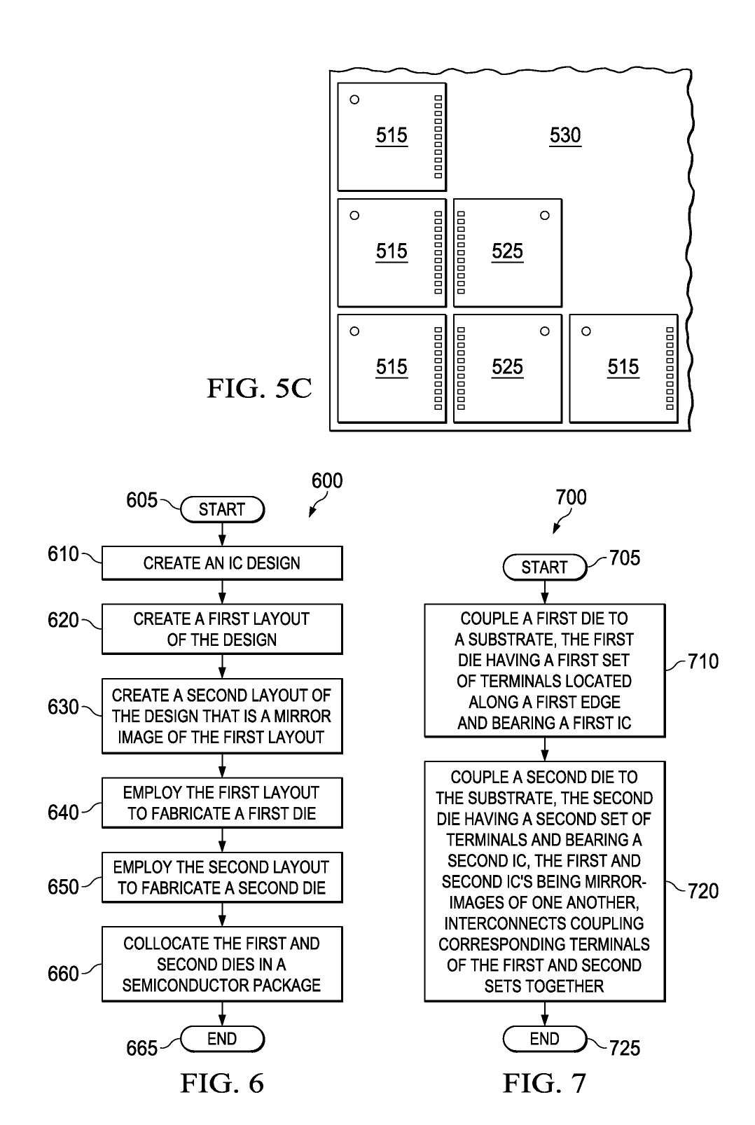

FIGS. 5A-C are plan views of a portion of a wafer illustrating two embodiments of manufacturing wafers of dies;

FIG. 6 is a flow diagram of one embodiment of a method of manufacturing a semiconductor package; and

FIG. 7 is a flow diagram of another embodiment of a method of manufacturing a semiconductor package.

### DETAILED DESCRIPTION

As stated above, the conventional arrangement described above (in which two identical IC dies are placed side by side and the interconnections bridging like terminals in the dies extend from the left-hand side of the left die to the left-hand side of the right die) continues to be proven and useful. However, it is realized herein that such arrangement has substantial limits.

Most notably, the demand for ever-higher performance from ICs has driven signal speeds to the point that the length of the interconnects required to span a side of one die to the corresponding side of the other die is too great; setup violations become more prevalent as speed-of-light limitations cause signals to arrive too late. It is realized that, for this reason, a fundamentally different approach is needed, and one that allows interconnections to be shorter and thus faster.

While stacking IC dies over one other has been contemplated to shorten interconnect length and reduce signal delays, they suffer problems of their own, including thermal problems. It is further realized that a fundamentally different approach is needed that does not involve stacking identical IC dies.

Accordingly, introduced herein are various embodiments of a semiconductor package containing two interconnected IC dies having identical circuitry designs. However, rather than the IC dies themselves being identical, they are mirror images of one another in that the entire pattern of circuitry laid out on one die is a mirror-image of the entire pattern of circuitry laid out on the other. Further, the entire pattern in each layer of circuitry laid out on one die is a mirror-image of its counterpart pattern in each corresponding layer laid out on the other die. One may properly regard one die as being left-handed and the other die as being right-handed. As a result, at least some of the interconnections spanning the dies are substantially shorter than they otherwise would be, and the costs of labor and material involved in designing and fabricating multi-die semiconductor packaging are reduced.

As will be understood, some embodiments of the novel semiconductor package may be manufactured by employing a software command to “flip” the entirety of each layer of a layout. Layouts are saved both before and after issuance of the flip command, resulting in mirror-image IC layouts, which can then be used to fabricate the mirror-image IC dies. Those skilled in the art understand that while the flip command is itself conventional, it has only been employed to flip particular functional blocks (sometimes called hard macros, modules or IP blocks) and never entire designs. Those skilled in the pertinent art understand that no motivation would exist to employ a flip command to flip an entire design absent the novel realizations and need for mirror-image IC dies described above, because a designer would instead begin the design process by laying out a design appropriate to the context in which the resulting IC die would be employed.

Using a pair of mirror-image IC dies instead of identical IC dies is also counterintuitive, because it necessarily increases the number of unique parts in the semiconductor design. Conventional wisdom dictates that numbers of unique parts should be kept as low as possible to reduce design, manufacturing and inventory storage costs. But it is realized that the time and effort spent in creating the mirror-image IC dies are negligible compared to the significant improvement a mirror-image IC die pair provides over an identical IC die pair.

It is realized that using ‘mirror-image’ IC die pair in a semiconductor package may significantly shorten the length of interconnects between the corresponding terminals of the paired IC dies. A ‘mirror image’ IC dies refers to an IC die having a spatial arrangement that corresponds to that of another IC die except that the right-to-left or East-to-West sense on one IC die corresponds to the left-to-right or West-to-East sense on the other. The ‘mirror-image’ IC die pair in the present disclosure would comprise a right-handed die and a left-handed die that are placed side-by-side on a common substrate with their edges having terminals for interconnects being adjacent to one another. As the corresponding terminals are closely situated to one another, one may shorten the lengths of interconnects and reduce latency and power consumption thereof.

As used throughout in the present disclosure, the term “IC die” or simply “die” refers to any monolithic electronic device or circuit that may be coupled to a substrate inside a semiconductor package. The term “IC” or “integrated circuit” refers to circuitry embedded in a silicon die.

FIG. 1 is an elevational view of one embodiment of a semiconductor package 100 at an intermediate stage of manufacture. As shown, the semiconductor package 100 includes first (right-handed) mirror-image IC die 120 and a second (left-handed) mirror-image IC die 130 coupled to a common substrate 110. Interconnects 140 couple the corresponding terminals 140 associated with adjacent edges of the two mirror-image IC dies 120, 130 together. In one embodiment, the substrate 110 is a silicon interposer.

Referring to FIG. 2, a plan view of the semiconductor package 100 of FIG. 1 at an intermediate stage of manufacture. First 120 and second 130 mirror-image IC dies are placed side-by-side with the same North-South orientation on the substrate 110. It is understood that the semiconductor package 100 may be in various formats including, but not limited to: a multi-chip module (MCM) format, 2.5D IC format or a system-on-a-chip (SoC) format.

The first mirror-image IC die 120 has North 212 and South edges 214 extending along the length of the substrate 110 and has East 216 and West 218 edges extending along the width of the substrate 110. The first IC die 120 also has a set of terminals 230 located along the East edge 216 and at least one Integrated circuit (“IC”) 250 that substantially occupies an area of the first IC die 120. In various embodiments, the first IC die 120 includes further sets of terminals located along other edges thereof.

The second IC die 130 has North 222 and South edges 224 extending along the length of the substrate 110 and has East 226 and West 228 edges extending along the width of the substrate 110. The second IC die 130 also has a set of terminals 240 located along the West edge 228 and also has at least one IC 260 that substantially occupies an area of the second IC die 130. In various embodiments, the second IC die 130 includes further sets of terminals located along other edges thereof.

Still referring to FIG. 2, the East edge 216 of the first mirror-image IC die 120 and the West edge 228 of the second mirror-image IC die 130 are placed side-by-side and substantially parallel with one another. Interconnects 140 couple the corresponding terminals 230 and 240 of the first 120 and second 130 mirror-image IC dies together. Interconnects 140 lie outside of the areas of the first and second ICs and are substantially parallel to one another.

FIG. 3 provides a plan view of another embodiment of a semiconductor package 300 at an intermediate stage of manufacture. The semiconductor package 300 includes a first pair 320 of mirror-image IC dies and a second pair 330 of mirror-image IC dies coupled to a common substrate 310. Similar to the embodiment of the mirror-image IC die pair of FIGS. 1-2, the mirror-image IC dies of the first and second pair 320, 330 are located side-by-side with same North-South orientation, with interconnects 340 coupling the corresponding terminals of the mirror-image IC dies. It is understood that although the semiconductor package 300 in this embodiment has two pairs of mirror-image IC dies, the semiconductor package 300 may have more than two pairs of mirror-image IC dies.

FIG. 4 shows an elevational view of yet another embodiment of a semiconductor package 400 at an intermediate stage of manufacture. The semiconductor package 400 includes two mirror-image IC dies 420 and 430 that are joined to one another at a die level with interconnects 440. The interconnects 440 are located in the IC dies 420, 430.

FIGS. 5A-C show plan views of various fields of wafers used in creating mirror-image IC die pairs. In FIGS. 5A-B, a first field of the wafer 510 of right-handed IC dies 515 and a second field of the wafer 520 of left-handed IC dies 525 are created separately, i.e., on separate wafers using separate reticles. In this exemplary embodiment, the first field of the wafer 510 of the right-handed IC dies 515 may be patterned on a single field of the wafer using a reticle bearing a pattern for a right-handed IC. Concurrently with the first field of the wafer 510, the second field of the wafer 520 of the left-handed IC dies 525 may be patterned on another wafer using a reticle bearing a pattern for a left-handed IC. It is understood than the first and second fields of the wafers 510, 520 may be patterned sequentially.

In another exemplary embodiment shown in FIG. 5C, another field of wafer 530 including both the right-handed and left-handed ICs 515, 525 is provided. A reticle bearing patterns for both the right-handed and left-handed ICs 515, 525 as shown in FIG. 5C is used to pattern a single wafer. Because the right-handed and left-handed IC dies 515, 525 may be provided in the single wafer, reticle tooling cost in this embodiment may be less expensive cheaper than the embodiments of FIGS. 5A-B.

Turning now to FIG. 6, illustrated is an exemplary method 600 for manufacturing a semiconductor package. After a start step at 605, an IC design is created at step 610. In a step 620, a first layout of the IC design that has multiple layers is created. In a step 630, a second layout of the design that is a mirror-image of the first layout is created. It is understood that the first and second layouts may be layouts for right-handed and left-handed IC dies or vice-versa. Creating the second layout of the IC design includes creating a mirror-image for each layer of multiple layers of the first layout by flipping each layer within a software environment. In one specific embodiment, flipping is executed using a “Global” command provided in an IC compiler tool commercially available from Mentor Graphics Corporation, of Wilsonville, Oreg., USA. In addition to the above-mentioned IC compiler, other conventional or later-developed IC compilers or layout tools may be employed to carry out the creation of the mirror-image layout.

In steps 640, 650, first and second dies are fabricated employing the first and the second layouts, respectively. The steps 640, 650 may be carried out sequentially using two reticles as described in FIGS. 5A-B or concurrently using a single reticle as described in FIG. 5C. In a step 660, the fabricated first and second dies are collocated in the semiconductor package. More specifically, the collocated first and second dies are located side-by-side on a common substrate with the respective edges having terminals for interconnects adjacent to one another. Substantially parallel interconnects are formed between the corresponding terminals. In the illustrated embodiment, the interconnects are formed on or in the common substrate before the first and second dies are located on the common substrate. It is understood that the semiconductor package may be in various formats including, but not limited to, a multi-chip module format, 2.5D format and a SoC format. The method then ends in an end step 665.

Turning to FIG. 7, illustrated is another exemplary method 700 of manufacturing a semiconductor package. After a start step 705, a first die is coupled to a substrate in a step 710. The first die has a first set of terminals located along a first edge and a first IC that substantially occupies an area of the first die. It is understood that the first die may have further sets of terminals located along other edges of the first die.

In step 720, a second die is coupled to the substrate. The second die has a second set of terminals and a second IC that substantially occupies an area of the second die. The first and second ICs are mirror-images of one another and collocated in a common substrate such that the first edge of the first die and the second edge of the second die are substantially parallel and side-by-side with one another, resulting in the interconnects that couple the corresponding terminals in the first and second edges being substantially parallel. In the illustrated embodiment, the interconnects lie outside of the areas of the first and second ICs. In certain embodiments, the second die has further sets of terminals located along other edges of the second die. It is also understood that the semiconductor package may be in various formats including, but not limited to, a multi-chip module format, 2.5D format and a SoC format. The method ends in an end step 725.

Those skilled in the art to which this application relates will appreciate that other and further additions, deletions, substitutions and modifications may be made to the described embodiments.

What is claimed is:

1. A semiconductor package, comprising:
a substrate;
a first die coupled to said substrate, said first die having a first set of terminals located along a first edge and bearing a first integrated circuit (IC) that substantially occupies an area of said first die;
a second die coupled to said substrate, said second die having a second set of terminals and bearing a second IC that substantially occupies an area of said second die, said first and second ICS being mirror-images of one another; and
interconnects coupling corresponding terminals of said first and second sets together.

2. The semiconductor package as recited in claim 1 wherein said interconnects are substantially parallel.

3. The semiconductor package as recited in claim 1 wherein said interconnects lie outside of said areas of said first and second ICs.

4. The semiconductor package as recited in claim 1 wherein said multi-chip module is in a format selected from the group consisting of:
a multi-chip module format,
a 2.5D format, and
a SoC format.

5. The semiconductor package as recited in claim 1 wherein said first and second die have further sets of terminals located along other edges thereof.

6. The semiconductor package as recited in claim 1 wherein said first and second edges are substantially parallel and side-by-side with one another.

7. The semiconductor package as recited in claim 1 wherein said interconnects are located on or in said substrate.

8. A method of manufacturing a semiconductor package, comprising:
coupling a first die to a substrate, said first die having a first set of terminals located along a first edge and bearing a first integrated circuit (IC) that substantially occupies an area of said first die;
coupling a second die to said substrate, said second die having a second set of terminals and bearing a second IC that substantially occupies an area of said second die, said first and second ICS being mirror-images of one another, interconnects coupling corresponding terminals of said first and second sets together.

9. The method as recited in claim 8 wherein said interconnects are substantially parallel.

10. The method as recited in claim 8 wherein said interconnects lie outside of said areas of said first and second ICs.

11. The method as recited in claim 8 wherein said semiconductor package is in a format selected from the group consisting of:
a multi-chip module,
a 2.5D format, and
a SoC format.

12. The method as recited in claim 8 wherein said first and second die have further sets of terminals located along other edges thereof.

13. The method as recited in claim 8 wherein said first and second edges are substantially parallel and side-by-side with one another.

14. The method as recited in claim 8, further comprising forming said interconnects on or in said substrate.

15. A method of manufacturing a semiconductor package, comprising:
creating an integrated circuit (IC) design;
creating a first layout of said design that has multiple layers;
creating a second layout of said design that is a mirror image of said first layout, corresponding ones of said multiple layers of said first and second layouts being mirror images of one another;
employing said first layout to fabricate a first die;
employing said second layout to fabricate a second die; and
collocating said first and second dies in said semiconductor package.

16. The method as recited in claim 15 wherein said creating said second layout comprises creating a mirror image of each of said multiple layers of said first layout.

17. The method as recited in claim 15 wherein said employing said first layout comprises employing said layout and a wafer to fabricate a plurality of first dies.

18. The method as recited in claim 15 wherein said employing said first layout and said employing said second layout are carried concurrently using a single set of reticles.

19. The method as recited in claim 15 further comprising forming substantially parallel interconnects between a first set of terminals located along a first edge of said first die and a second edge of said second die.

20. The method as recited in claim 15 wherein said semiconductor package is in a format selected from the group consisting of:
a multi-chip module,
a 2.5D format, and
a SoC format.
